(19) United States
(12) Patent Application Publication
(10) Pub. No.: US 2016/0358891 A1
(43) Pub. Date: Dec. 8, 2016

(54) OPOSSUM-DIE PACKAGE-ON-PACKAGE APPARATUS

(71) Applicant: INTEL CORPORATION, Santa Clara, CA (US)

(72) Inventors: Christian GEISSLER, Teugn, BY (DE); Thorsten MEYER, Regensburg, BY (DE)

(21) Appl. No.: 14/778,018

(22) PCT Filed: Dec. 15, 2014
(86) PCT No.: PCT/US2014/070407

§ 371 Date: Sep. 17, 2015

(51) Int. Cl. H01L 25/065; H01L 25/00

(52) U.S. Cl. CPC H01L 25/0657; H01L 25/50; H01L 2225/0652; H01L 2225/06548; H01L 2225/06555

(57) ABSTRACT

An apparatus including a first package coupled to a second package, wherein each of the first package and the second package has a first side and an opposite second side; a first die coupled to the first package; and a second die coupled to the second side of the second package, wherein the first package is coupled to the second package in a stacked arrangement such that the first side of the second package faces the second side of the first package. A method including coupling a first package to a second package in a stacked configuration, wherein the first package includes a first package substrate and a first die and the second package includes a second package substrate and a second die, wherein the second die is disposed on a side of the second package substrate opposite the first package substrate.

### BACKGROUND

Field

Integrated circuit packaging.

Description of Related Art

For mobile applications small package form factor (footprint and z-height) and low packaging costs are important requirements for new products. Package on package (PoP) assembly in which one package is connected to another package in a stacked arrangement (one on the other in a z-direction) is used to reduce a module footprint (e.g., memory on top of application processor). While reducing xy-direction footprint, a PoP configuration increases the z-direction thickness or height (“z-height”) of the module. Current state of the art PoP module technologies have z-heights on the order of one millimeter or greater. Typical PoP solutions also allow a limited number of interconnects between top and bottom package. Typically, the interconnects are located in the fan-out area or peripheral area of the bottom package. An additional rerouting layer or tighter geometries for the interconnects can be used to increase the interconnect bandwidth but such solutions tend to increase packaging costs.

### BRIEF DESCRIPTION OF THE DRAWINGS

FIG. 1 shows a cross-sectional side view of an embodiment of a package on package (PoP) assembly including a bottom or supporting package having a die in a hanging or opossum configuration relative to a package substrate to which it is attached.

FIG. 2 shows a cross-sectional side view of another embodiment of a PoP assembly employing a bottom or supporting package having a die in a hanging or opossum configuration relative to a package substrate to which it is attached.

FIG. 3 shows a cross-sectional side view of another embodiment of a PoP assembly where an underlying or supporting package is based on wafer level packaging, particularly an embedded wafer level ball grid array (e.g., eWLB) package with peripheral interconnects to the top package.

FIG. 4 shows a cross-sectional side view of another embodiment of a PoP assembly with an opossum fanout wafer level package as bottom package with areal interconnects to the top package.

FIG. 5 shows cross-sectional side view of pre-PoP assembly using eWLB on eWLB opossum configuration.

FIG. 6 shows a side view of a mold carrier having an adhesive foil disposed on a surface thereof and a number of via bars placed on the adhesive foil.

FIG. 7 shows the structure of FIG. 6 following the separation of the via bars and molding material from the adhesive layer and introduction of a redistribution layer on the structure and the connection of a die thereto.

FIG. 8 shows the structure of FIG. 7 following the thinning of the molding material.

The processing sequence can also be different: thinning of the body before placing solder balls and opossum die.

FIG. 9 illustrates an embodiment of a computing device.

### DETAILED DESCRIPTION

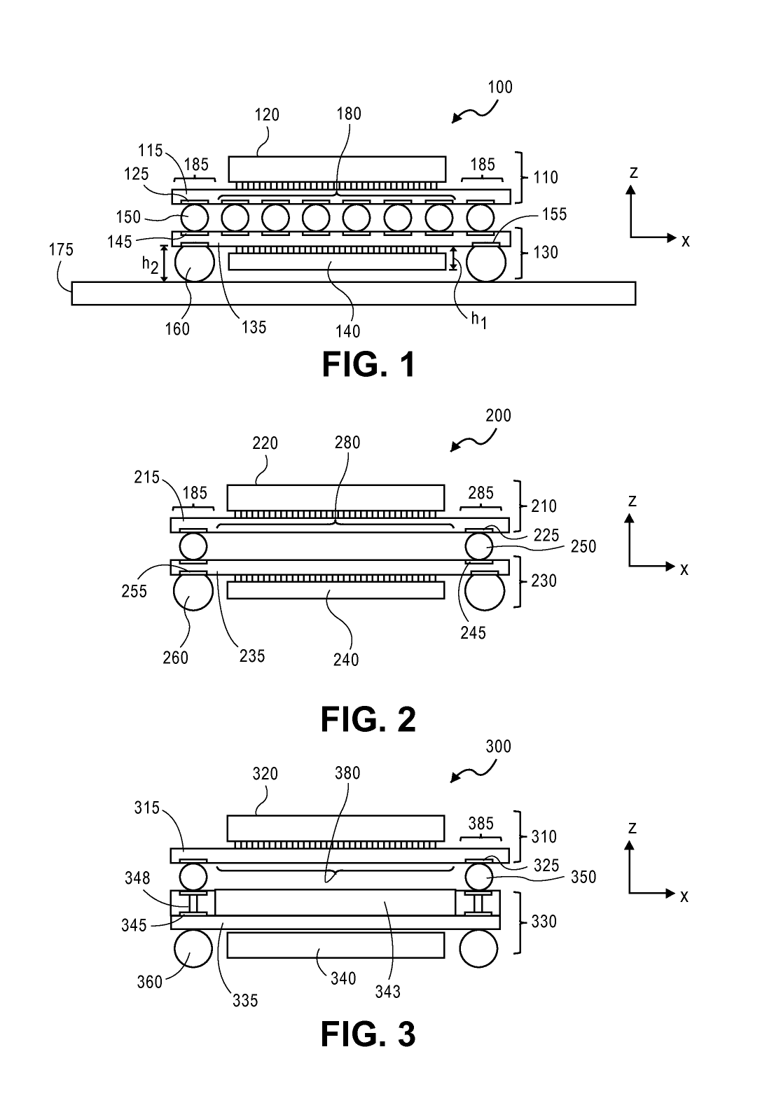

FIG. 1 shows a cross-sectional side view of an embodiment of a package on package (PoP) assembly including a bottom or supporting package having a die in a hanging or opossum configuration relative to a package substrate to which it is attached. Referring to FIG. 1, PoP assembly 100 includes package 110 connected to package 230 in a stacked arrangement (package 110 over or on package 130 in a z-direction as illustrated).

Package 110 includes package substrate 115 to which die 120 is electrically and physically connected to a surface thereof through, for example, a bumping or reflow process between contacts points of the die and the package substrate, respectively, optionally including an underfill. Representatively, die 120 is a memory die. Package 110 also includes interconnects 150 (e.g., solder bumps) operable to connect package 110 to bottom or support package 130.

Package 130 of PoP assembly 100 illustrated in FIG. 1 includes package substrate 135 to which die 140 (e.g., a flip chip microprocessor) is electrically and physically connected through a bumping or reflow process optionally including an underfill. As illustrated in FIG. 1, die 140 is connected to a side of package substrate 135 such that die 140 is below package substrate 135 relative to a z-direction and is therefore in a opossum or hanging die configuration relative to package substrate 135 as viewed. In other words, where each packaging substrate includes a die side to which a respective die is connected (die 120 to package substrate 115 and die 140 to package substrate 135) and an opposite or backside, a backside of package substrate 115 faces a backside of package substrate 135.

In PoP assembly 100 die 140 is in a hanging or opossum configuration with regard to its attachment to package substrate 145 and relative to the attachment of die 120 to package substrate 115, as viewed, with package 110 on or above package 130. Package substrate 135 also includes contact pads 155 on a die side of the package substrate. In the embodiment shown, PoP assembly 100 is connected to substrate 175 that is, for example, a printed circuit board for use representatively in a mobile application such as a phone or other portable computing device. PoP assembly 100 is connected to substrate 175 through solder connections 160 (solder balls) between contact pads 155 of package substrate 135 and corresponding contact pads of substrate 175. In one embodiment, a thickness or height, h₁, of die 140 including any interconnect to the substrate and redistribution layer is less than a thickness or height, h₂, of solder connection 160.

Referring to assembly 100, with regard to connection of package 110 to package 130, the connection can be made through solder connections to contacts or contact pads arranged about an areal surface of each package. Representatively, FIG. 1 shows package substrate 115 having an interior area 180 and peripheral area 185, interior area 180 and peripheral area 185 collectively defining an areal surface of the package. As illustrated, contact pads are arranged about interior area 180 and also about peripheral area 185. Such contact pads may be formed during the substrate fabrication phase by routing or distributing traces or interconnects to interior area 185 and forming contact pads to the traces or interconnects. The ability to use interior area 180 of package substrate 115 for interconnection points between the substrate and package 130 offers an increased number of interconnection points compared to a package substrate with only peripherally disposed contact pads (only in peripheral area 185). FIG. 1 shows package substrate 135 having contact pads 145 disposed on a surface thereof opposite a side of the substrate to which die 140 is connected. Contact pads 145 are aligned with contact pads 125 of package substrate 115 (including in an interior area of the package substrate) and solder connections 150 (solder balls) connect the packages through the respective contact pads.

FIG. 2 shows a cross-sectional side view of another embodiment of a PoP assembly employing a bottom or supporting package having a die in a hanging or opossum configuration relative to a package substrate to which it is attached. Referring to FIG. 2, assembly 200 includes package 210 connected to package 230 in a stacked arrangement (one over or on the other in a z-direction as illustrated). Package 210 includes package substrate 215 to which die 220 is electrically and physically connected to a surface thereof through, for example, a bumping or a reflow process optionally including an underfill process. Representatively, die 220 is a flip chip memory die. FIG. 2 also shows package 210 including contact pads 225 on a side of the substrate opposite a side to which die 220 is connected. Contact pads 225 are disposed in area 285 that is peripheral to interior area 280 of the package substrate. In one embodiment, contact pads 225 are disposed along the periphery or edge of four sides of a surface of package substrate 215 having a rectangular or square shape.

Package 230 of PoP assembly 200 in FIG. 2 includes package substrate 235 to which die 240 (e.g., a flip chip microprocessor) is connected through a bumping or reflow process optionally including an underfilling process. As illustrated, die 240 is connected to a side of package substrate 235 such that die 240 is below package substrate 235 relative to a z-direction and is therefore in an opossum or hanging configuration relative to package substrate 235. Package substrate 235 of package 230 includes contact pads 245 disposed on a side of the substrate opposite a side to which die 240 is attached. Contact pads 245 are disposed in a peripheral arrangement on a surface of the package substrate and are aligned with contact pads 225 of package 210. FIG. 2 shows solder connections 250 (solder balls) disposed between contact pads 225 of package 210 and contact pads 245 of package 230 to electrically connect the packages. Package substrate 235 of package 230 also includes contact pads 255 disposed on a die side of the package substrate. FIG. 2 shows solder connections 260 connected to contact pads 255 that are operable to connect PoP assembly 200 to a substrate such as a printed circuit board.

In the embodiment shown in each of FIG. 1 and FIG. 2, each assembly representatively includes a package such as a commercial memory package disposed on a flip chip ball grid array package having an opossum or hanging die configuration. By utilizing an opossum or hanging die configuration for the bottom or supporting package of a PoP assembly (e.g., package 130 of FIG. 1, package 230 of FIG. 2), a z-height of the assembly is minimized. In one embodiment, a representative z-height for both package assembly 100 in FIG. 1 and package assembly 200 in FIG. 2 is on the order of one millimeter (mm).

FIG. 3 shows a cross-sectional side view of another embodiment of a PoP assembly where an underlying or supporting package is based on wafer level packaging, particularly an embedded wafer level ball grid array (e.g., eWLB) package. For eWLB, a package is formed around a redistribution layer with respect to die contacts. FIG. 3 shows a cross-sectional side view of PoP assembly 300 including package 310 electrically connected to package 330 in a stacked arrangement with package 310 on and above package 330 in a z-direction. Package 310 includes package substrate 315. Electrically and physically connected to contacts on a surface of package substrate 315 (top surface as viewed) is die 320 of, for example, memory die. Package substrate 315 includes contact pads 325 disposed about a peripheral area of the package substrate on a side opposite a side to which die 320 is attached. Peripheral area 385 is peripheral to interior area 380 and, in one embodiment, surrounds a periphery or edge of each side or a four-sided rectangular package substrate.

Package 330 of PoP assembly 300 in FIG. 3 includes die 340 of, for example, a microprocessor directly connected to redistribution layer 335. Redistribution layer 335 includes contact pads on a die side (to connect to die 340) and contact pads 345 on a side opposite of side to which die 340 is connected with electrical traces and interconnects therebetween. Connected to contact pads 345 are via bars 348 embedded in or disposed in molding material 343. As illustrated, via bars 348 are formed around a peripheral area of the package substrate and are aligned with contact pads 325 of package substrate 315. In another embodiment, through mold vias (TMVs) may be used as an alternative to via bars.

Package substrate 310 connected to package substrate 330 to solder connections 350 between contact pads 325 and via bars 348. Disposed on a side of package 330 including die 340 of contact pads to which solder connections 360 are connected to electrically connect assembly 300 to a substrate, which is a printed circuit board.

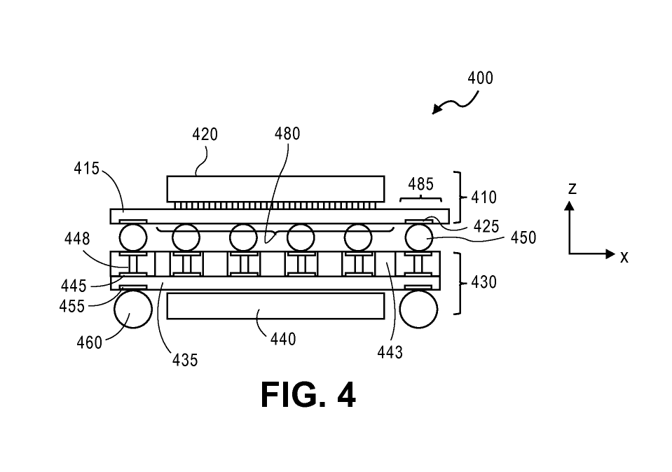

FIG. 4 shows a cross-sectional side view of another embodiment of a PoP assembly. Assembly 400 includes package 410 connected to package 430 in a stacked configuration relative to a z-direction with package 410 above package 430 as viewed. In one embodiment, package 410 includes die 420 such as a memory die, electrically and physically connected to contact points on a die or first side of package substrate 415. Package substrate 415 has contact pads 425 on a second side of the package substrate opposite the die side. Such contact pads are disposed about interior area 480 and peripheral area 485 of the package substrate. In one embodiment, package 410 is a flip chip ball grid array package.

Package 430 in assembly 400 illustrated in FIG. 4 includes die 440 disposed in eWLB arrangement including redistribution layer 435 and via bars 448 embedded in molding material 443. Redistribution layer of a dielectric material includes contact points on a first side (bottom side as viewed) that are connected to contact points of die 440, conductive interconnects/traces and interconnects to redistribute the connection to second contact points on a second side of redistribution layer 435 (top side as viewed). Respective ones of such contact points are connected to individual via bars 448. Via bars 448 are connected on one side to redistribution layer 435 and on an opposite side provide contact points or pads for connecting package 430 to package 410. FIG. 4 shows solder connections 450 (solder balls) disposed between contact pads 425 of package 410 and via bars 448 of package 430. FIG. 4 also shows solder connections 460 connected to contact pads on a die side of redistribution layer 435 (a side opposite via bars 448). Solder connections 460 are operable, in one embodiment, to connect assembly 400 to a substrate such as a printed circuit board.

By using an eWLB package including a die in a opossum or hanging configuration as in FIG. 3 and FIG. 4, a z-height of a PoP assembly of 1 mm or less may be realized. In addition, the opossum or hanging die configuration of a bottom package (as viewed in FIG. 3 and FIG. 4) provides an interface area between the packages, interior area 380 (FIG. 3) and interior area 480 (FIG. 4) for interconnects. FIG. 4 in particular shows the utilization of the interior interface area for interconnects between the packages with a ball grid array arrangement.

The advantages described with respect to the above embodiments include a z-height of a package stack of 1 mm or less; an area array capability for a top package; direct contact of a top package to a bottom package substrate providing a reduced interconnect from top package to bottom package; a possibility for direct die attachment; and an opportunity for discreet passive devices to be attached while maintaining a minimal package height.

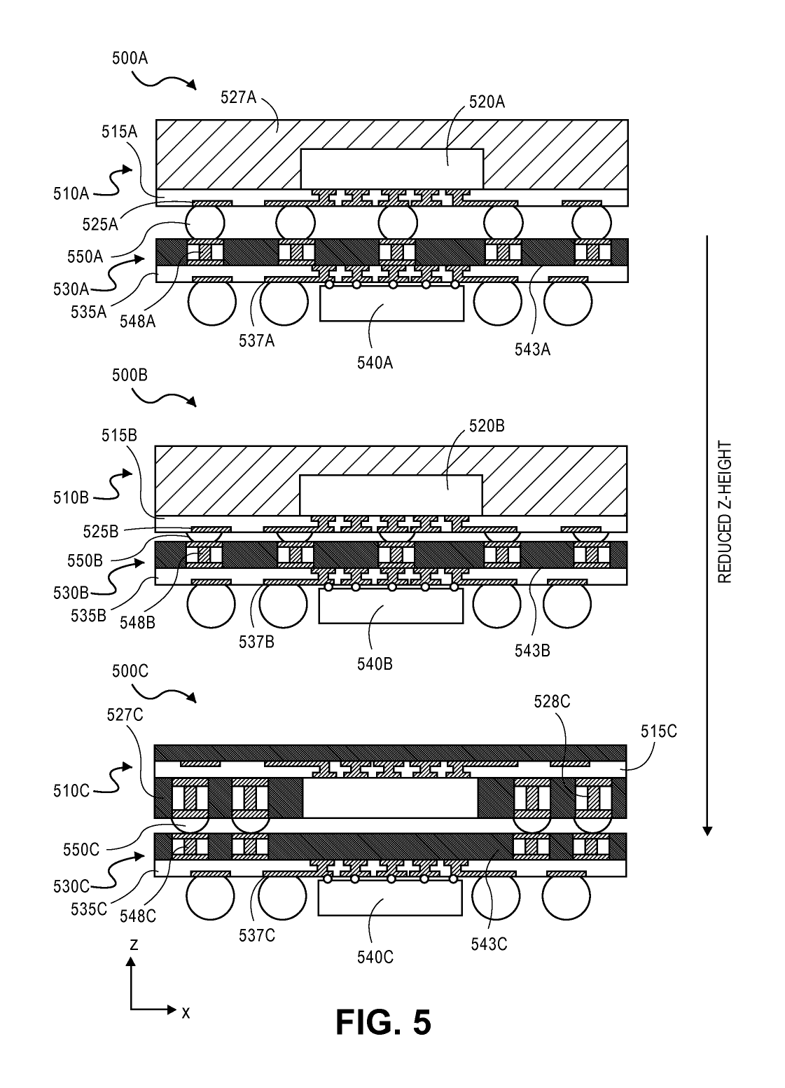

FIG. 5 shows a cross-sectional side view of three PoP assemblies each using eWLB on eWLB opossum configurations. Package assembly 500A includes top package 510A (as viewed) electrically connected to bottom package 530A in a stacked configuration. Package 510A includes die 520A of, for example, a memory die, electrically and physically connected on a device side to redistribution layer 515A. Redistribution layer 515 includes contact points 525A on a side of redistribution layer opposite a side connected to die 520A. Package 510A also shows molding material 527A embedding die 520A.

Package 530A includes die 540A connected on a die side to redistribution layer 535A with an opposite side of redistribution layer 535A connected to via bars 548A embedded in molding material 543A. As illustrated, package 510A is connected to package 535A through solder connections 550A (solder balls) between contact pads 525A of package 510A and contact points associated with via bars 548A of package 530A. As illustrated, die 540A of package 530A is in a opossum or hanging configuration disposed below redistribution layer 535A as viewed.

PoP assembly 500B includes package 510B connected to package 530B in a stacked configuration (is disposed on or above package 530B as viewed). Package 510B, in one embodiment, is similar to package 510A and includes die 520B connected to redistribution layer 515B and the die embedded in molding material 527B. Redistribution layer 515B includes contact pads 525B disposed on a side of redistribution layer opposite a side to which die 520B is connected.

Package 530B of PoP assembly 500B illustrated in FIG. 5 is, in one embodiment, similar to package 530A of assembly 500A and includes die 540B electrically connected to redistribution layer 535B and the redistribution layer electrically connected to via bars 548B that are embedded in molding material 543B. In assembly 500B, package 510B is electrically connected to package 530B using solder on pad (SOP) or semi-spherical solder balls 550B. In this manner, a z-height of the interconnection between contact pads 525B of package 510B and contact points of via bars 548B of package 530B are minimized. Thus, PoP assembly 500B has a z-height less than a z-height of package assembly 500A.

PoP assembly 500C include first package 510C connected to package 530C in a stacked configuration with package 510C on or above package 530C as viewed. In this embodiment, each of package 510C and package 530C includes a die in a opossum or hanging configuration. Package 510C includes die 520C connected to redistribution layer 515C. FIG. 5 also shows via bars 528C connected on a die side of redistribution layer 515C. In this embodiment, both die 520C and via bars 528C are embedded in molding material 527C.

Package 530C in PoP assembly 500C is, in one embodiment, similar to package 530B and package 530A of assembly 500B and assembly 500A, respectively. Package 530C includes die 540C connected to redistribution layer 535C and via bars 548C extending from an opposite side of redistribution layer 535C and embedded in molding material 543C. FIG. 5 shows solder on pad (SOP) or semi-spherical solder balls 550C connected between contact points of via bars 528C of package 510C and contact points of via bars 548C of package 530C. As illustrated, PoP assembly 500C has a z-height or thickness less than PoP assembly 500B or PoP assembly 500A.

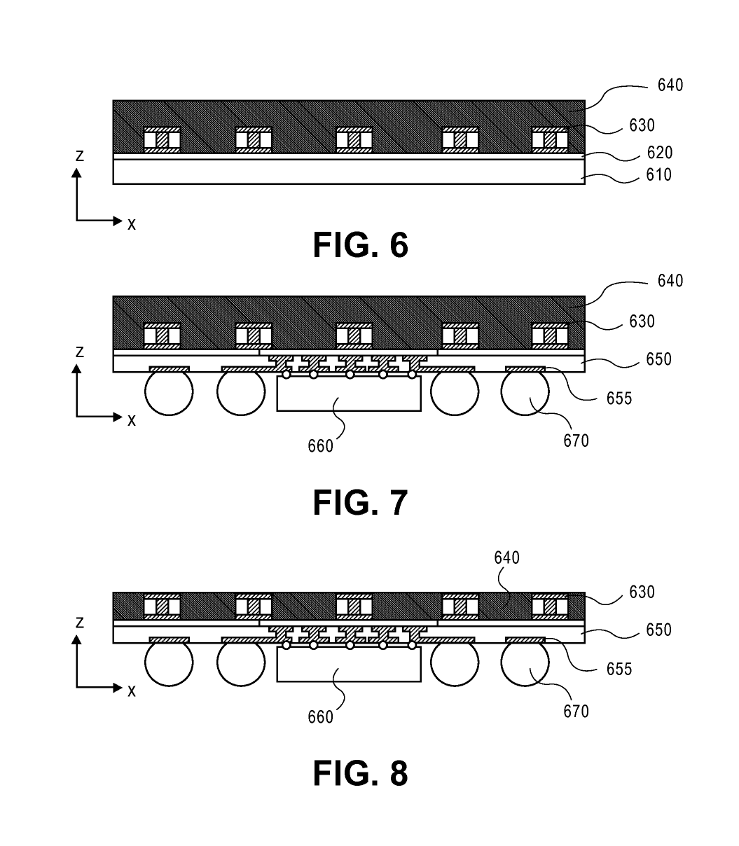

While techniques for forming a eWLB package are known, FIGS. 6-8 illustrate cross-sectional side views of a process of forming an eWLB package having an opossum or hanging die configuration, such as package 530A or package 530B in FIG. 5. FIG. 6 shows a side view of a mold carrier having an adhesive foil disposed on a surface thereof and a number of via bars placed on the adhesive foil. Mold carrier 610 is, for example, a stainless steel material to which adhesive foil 620 may be affixed. Via bars 630 are disposed on adhesive foil 620 with a respective contact point or pad in contact with the foil. Following the disposition of via bars 630 on adhesive foil 620, a molding material of, for example, liquid or granular mold compound is introduced on adhesive foil 620 to embed via bars 630.

FIG. 7 shows the structure of FIG. 6 following the separation of the via bars and molding material from the adhesive layer and introduction of a redistribution layer on the structure and the connection of a die thereto. In one embodiment, molding material 640 is separated from adhesive layer 620 by a debonding process using, for example, some thermal budget. Referring to FIG. 7, a redistribution layer is introduced by introducing dielectric layer 650 onto the surface created by a removal of adhesive layer 620 and patterning contacts to contact points or pads of via bars 630 using photolithography techniques, followed by plating techniques to form conductive vias and traces. Conductive vias and/or contact points or pads are also formed on or near a surface of dielectric layer 650 opposing the surface in contact with via bars 630 and molding material 640. FIG. 7 shows die 660 electrically and physically connected to such contact points or pads 655 as well as solder connections 670 (solder balls) connected to other ones of contact points or pads 655.

FIG. 8 shows the structure of FIG. 7 following the thinning of the molding material. Molding material 640 is thinned to expose a contact surface of each of via bars 630. Following thinning of the molding material, the package is assembled and can be connected to a second package for a PoP assembly. In another embodiment, the processing sequence can also be different: thinning of the body before placing solder balls and opossum die. As illustrated in FIG. 8, the package includes a die in an opossum or hanging die configuration (below the redistribution layer as viewed in a z-direction).

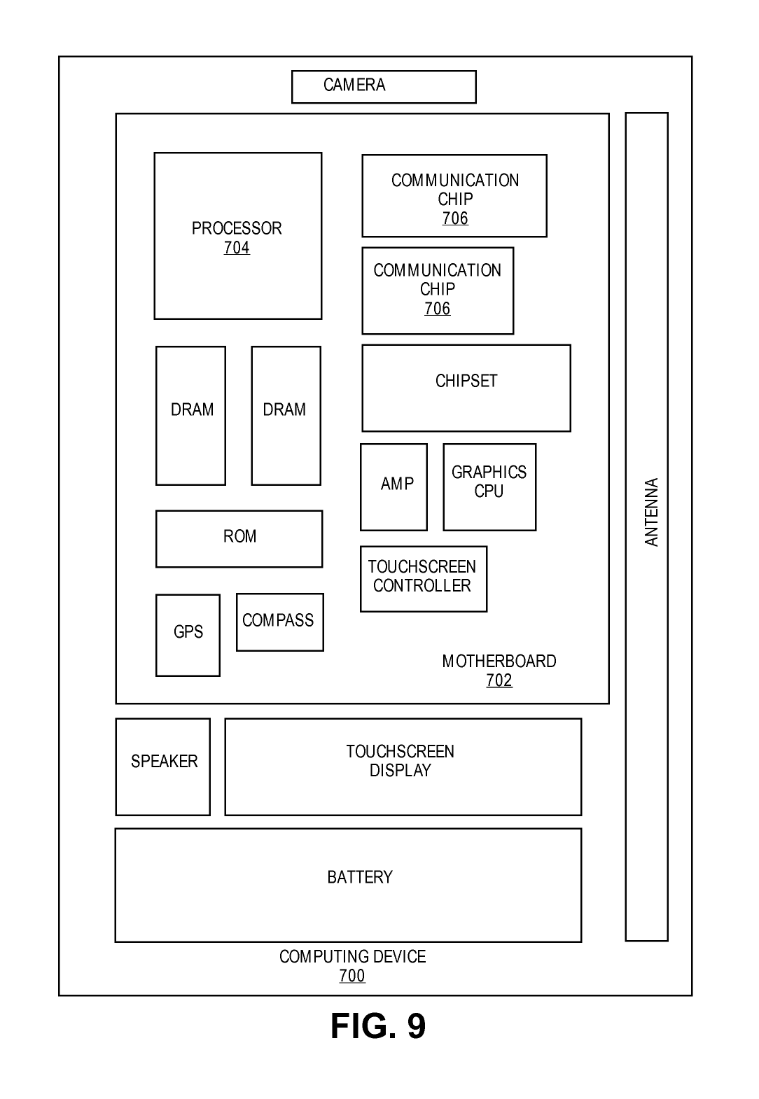

FIG. 9 illustrates computing device 700 in accordance with one implementation. Computing device 700 houses board 702. Board 702 may include a number of components, including but not limited to processor 704 and at least one communication chip 706. Processor 704 is physically and electrically coupled to board 702. In some implementations at least one communication chip 706 is also physically and electrically coupled to board 702. In further implementations, communication chip 706 is part of processor 704. A PoP assembly such as in the implementations described above may be utilized to include processor 404 and another chip (e.g., communication chip 406, a memory chip).

Depending on its applications, computing device 700 may include other components that may or may not be physically and electrically coupled to board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 706 enables wireless communications for the transfer of data to and from computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 700 may include a plurality of communication chips 706. For instance, first communication chip 706 may be dedicated to shorter range wireless communications such as Wi-Fi and Bluetooth and second communication chip 706 may be dedicated to longer range wireless communications such as GPS, EDGE, GPRS, CDMA, WiMAX, LTE, Ev-DO, and others.

Processor 704 of computing device 700 includes an integrated circuit die packaged within processor 704. The term “processor” may refer to any device or portion of a device that processes electronic data from registers and/or memory to transform that electronic data into other electronic data that may be stored in registers and/or memory.

Communication chip 706 also includes an integrated circuit die packaged within communication chip 706.

In further implementations, another component housed within computing device 700 may contain an integrated circuit die that includes one or more devices, such as transistors or metal interconnects.

In various implementations, computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 700 may be any other electronic device that processes data.

### EXAMPLES

Example 1 is an apparatus including a first package coupled to a second package, wherein each of the first package and the second package has a first side and an opposite second side; a first die coupled to the first package; and a second die coupled to the second side of the second package, wherein the first package is coupled to the second package in a stacked arrangement such that the first side of the second package faces the second side of the first package.

In Example 2, the first die in the apparatus of Example 1 is coupled to the first side of the first package.

In Example 3 the first package in the apparatus of Example 2 is coupled to the second package through contacts about the interior of a surface of each package.

In Example 4, the first package in the apparatus of Example 2 is coupled to the second package through contacts through peripherally arranged contact points.

In Example 5, the first die in the apparatus of Example 1 is coupled to the second side of the first package.

In Example 6, the first package in the apparatus of Example 5 is coupled to the second package through peripherally arranged contact points.

In Example 7, the second package in the apparatus of Example 1 includes a plurality of contact points on the first side and via bars coupled to respective ones of the plurality of contact points and to contact points on the second side of the first package.

In Example 8, the via bars in the apparatus of Example 7 are coupled to solder connections on the contact points on the second side of the first package.

In Example 9, the first die in the apparatus of Example 7 is coupled to the first side of the first package.

In Example 10, the first die in the apparatus of Example 7 is coupled to the second side of the first package.

Example 11 is an apparatus including a package on package configuration including a first package coupled to a second package in a stacked arrangement with the first package on the second package, the first package including a first package substrate and a first die and the second package including a second package substrate and a second die, wherein the second die is disposed on a side of the second package substrate opposite the first package substrate.

In Example 12, the first die in the apparatus of Example 11 is coupled to the side of the first package substrate opposite the second package substrate.

In Example 13, the first package in the apparatus of Example 12 is coupled to the second package through contacts about the interior of a surface of each package.

In Example 14, the first package in the apparatus of Example 12 is coupled to the second package through contacts through peripherally arranged contact points.

In Example 15, the first die in the apparatus of Example 11 is coupled to a side of the first package substrate that faces the second package substrate.

Example 16 is a method including coupling a first package to a second package in a stacked configuration, wherein the first package includes a first package substrate and a first die and the second package includes a second package substrate and a second die, wherein the second die is disposed on a side of the second package substrate opposite the first package substrate.

In Example 17, the first die in the method of Example 16 is coupled to the side of the first package substrate opposite the second package substrate.

In Example 18, coupling the first package to the second package in the method of Example 16 includes coupling through contacts about the interior of a surface of each package.

In Example 19, coupling the first package to the second package in the method of Example 16 includes coupling through contacts through peripherally arranged contact points.

In Example 20, the first die in the method of Example 16 is coupled to a side of the first package substrate that faces the second package substrate.

In Example 21, an integrated circuit package made by the method of any of Examples 16-20.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a first package coupled to a second package, wherein each of the first package and the second package has a first side and an opposite second side;
a first die coupled to the first package; and
a second die coupled to the second side of the second package,
wherein the first package is coupled to the second package in a stacked arrangement such that the first side of the second package faces the second side of the first package.

2. The apparatus of claim 1, wherein the first die is coupled to the first side of the first package.

3. The apparatus of claim 2, wherein the first package is coupled to the second package through contacts about the interior of a surface of each package.

4. The apparatus of claim 2, wherein the first package is coupled to the second package through contacts through peripherally arranged contact points.

5. The apparatus of claim 1, wherein the first die is coupled to the second side of the first package.

6. The apparatus of claim 5, wherein the first package is coupled to the second package through peripherally arranged contact points.

7. The apparatus of claim 1, wherein the second package comprises a plurality of contact points on the first side and via bars coupled to respective ones of the plurality of contact points and to contact points on the second side of the first package.

8. The apparatus of claim 7, wherein the via bars are coupled to solder connections on the contact points on the second side of the first package.

9. The apparatus of claim 7, wherein the first die is coupled to the first side of the first package.

10. The apparatus of claim 7, wherein the first die is coupled to the second side of the first package.

11. An apparatus comprising:
a package on package configuration comprising a first package coupled to a second package in a stacked arrangement with the first package on the second package, the first package comprising a first package substrate and a first die and the second package comprising a second package substrate and a second die, wherein the second die is disposed on a side of the second package substrate opposite the first package substrate.

12. The apparatus of claim 11, wherein the first die is coupled to the side of the first package substrate opposite the second package substrate.

13. The apparatus of claim 12, wherein the first package is coupled to the second package through contacts about the interior of a surface of each package.

14. The apparatus of claim 12, wherein the first package is coupled to the second package through contacts through peripherally arranged contact points.

15. The apparatus of claim 11, wherein the first die is coupled to a side of the first package substrate that faces the second package substrate.

16. A method comprising:
coupling a first package to a second package in a stacked configuration, wherein the first package comprises a first package substrate and a first die and the second package comprises a second package substrate and a second die, wherein the second die is disposed on a side of the second package substrate opposite the first package substrate.

17. The method of claim 16, wherein the first die is coupled to the side of the first package substrate opposite the second package substrate.

18. The method of claim 16, wherein coupling the first package to the second package comprising coupling through contacts about the interior of a surface of each package.

19. The method of claim 16, wherein coupling the first package to the second package comprising coupling through contacts through peripherally arranged contact points.

20. The method of claim 16, wherein the first die is coupled to a side of the first package substrate that faces the second package substrate.

21. An integrated circuit package made by the method of claim 16.
